(19) United States
(12) Patent Application Publication
(10) Pub. No.: US 2026/0164839 A1
(43) Pub. Date: Jun. 11, 2026

(54) SINGLE-PHOTON AVALANCHE DIODE (SPAD) DEVICES INCLUDING A SUPERLATTICE ADJACENT GUARD RING

(71) Applicant: Atomera Incorporated, Los Gatos, CA (US)

(72) Inventors: Ilya Rumyantsev, San Francisco, CA (US); Robert J. Mears, Wellesley, MA (US)

(21) Appl. No.: 19/415,027

(22) Filed: Dec. 10, 2025

Related U.S. Application Data
(60) Provisional application No. 63/730,089, filed on Dec. 10, 2024.

(51) Int. Cl. H10F 77/14; H10F 30/225

(52) U.S. Cl. CPC H10F 77/146; H10F 30/2255

(57) ABSTRACT

A single-photon avalanche diode (SPAD) device may include a semiconductor substrate having a first conductivity type, a deep well region in the semiconductor substrate having a second conductivity type different than the first conductivity type, and a multiplication region in the deep well region having the second conductivity type. The SPAD device may further include a central active region on the multiplication region and having the first conductivity type, a guard ring surrounding the central region and the multiplication region and having the first conductivity type, and a superlattice layer adjacent an interface between the multiplication region and the guard ring. The superlattice layer may include stacked groups of layers, with each group of layers comprising stacked base semiconductor monolayers defining a base semiconductor portion, and at least one non-semiconductor monolayer constrained within a crystal lattice of adjacent base semiconductor portions.

### CROSS-REFERENCE TO RELATED APPLICATIONS

This application claims the benefit of U.S. Provisional Patent Application No. 63/730,089, filed Dec. 10, 2024, which is hereby incorporated herein in its entirety by reference.

### TECHNICAL FIELD

The present disclosure generally relates to semiconductor devices, and, more particularly, to optical detector devices and associated methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region includes alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A single-photon avalanche diode (SPAD) device may include a semiconductor substrate having a first conductivity type, a deep well region in the semiconductor substrate having a second conductivity type different than the first conductivity type, and a multiplication region in the deep well region having the second conductivity type. The SPAD device may further include a central active region on the multiplication region and having the first conductivity type, a guard ring surrounding the central region and the multiplication region and having the first conductivity type, and a superlattice layer adjacent an interface between the multiplication region and the guard ring. The superlattice layer may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

In an example implementation, the superlattice layer may surround the guard ring. The SPAD device may further include a plurality of contact regions adjacent the guard ring. By way of example, the first conductivity type may comprise p-type, and the second conductivity type may comprise n-type.

In example implementations, the base semiconductor may comprise silicon, germanium, etc. Also by way of example, the at least one non-semiconductor monolayer may comprises a non-semiconductor selected from the group consisting of oxygen, nitrogen, fluorine, carbon, and carbon-oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional diagram of a single-photon avalanche diode (SPAD) device including a superlattice in accordance with an example embodiment.

FIG. 5 is a schematic cross-sectional diagram of an alternative embodiment of the SPAD device of FIG. 4.

FIG. 6 is a schematic cross-sectional diagram of another SPAD device including a superlattice in accordance with an example embodiment.

FIG. 7 is a schematic cross-sectional diagram of still another SPAD device including a superlattice in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

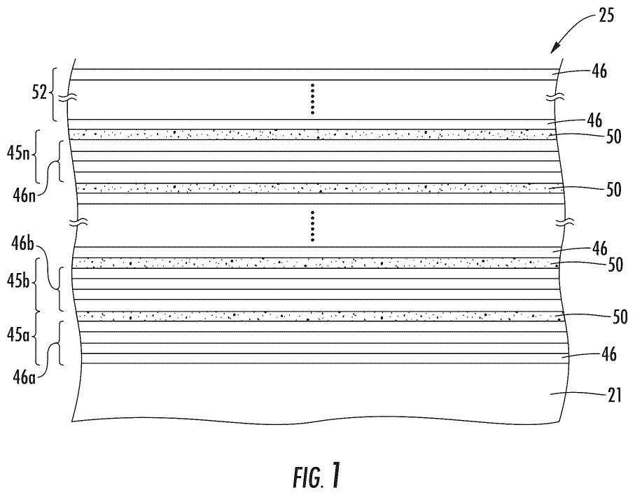

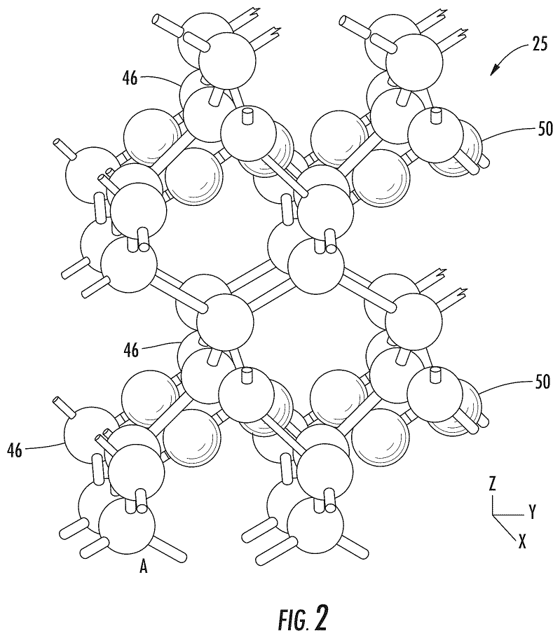

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably, between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

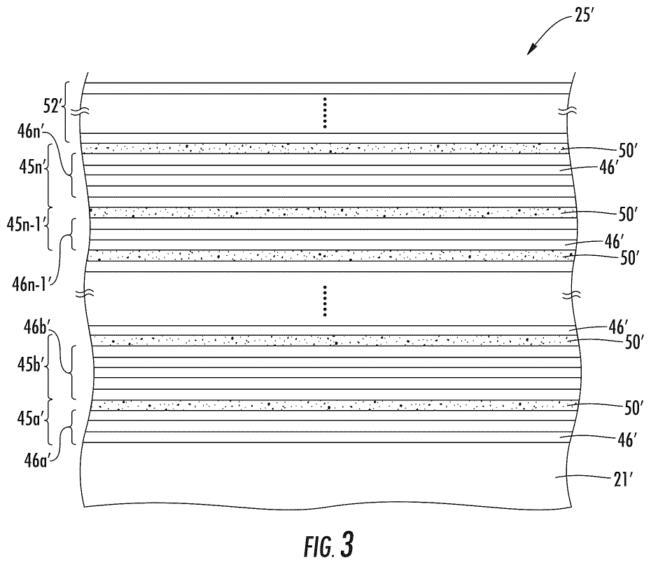

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

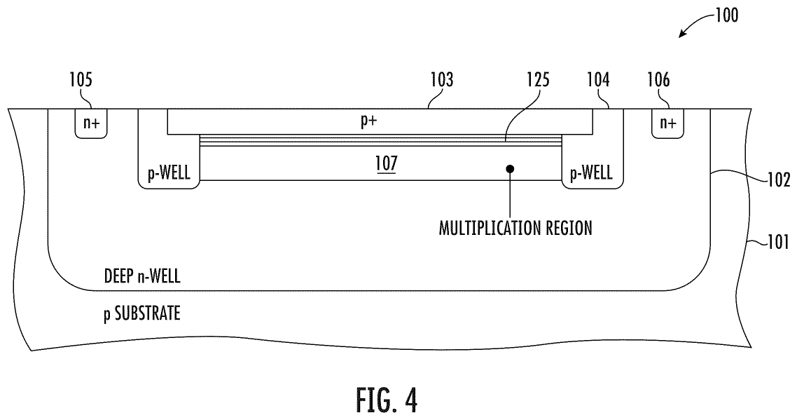

Turning now to FIG. 4, the above-described MST films may be incorporated within a single-photon avalanche diode (SPAD) device 100 to provide several technical advantages. Generally speaking, a SPAD is essentially a photodiode operating in Geiger mode above the breakdown voltage (BV), coupled to some quenching circuitry, typically a passive or dynamic resistor to stop the avalanche process initiated by the photon absorption.

The SPAD 100 illustratively includes a p-type substrate 101 with a deep n-well 102 therein. The SPAD 100 further illustratively includes a central p+ active region 103, and a p-well guard ring 104 surrounding the central p+ region. Contacts 105, 106 (n+) are also positioned in the deep n-well 102 adjacent the guard ring 104. Although not shown in FIG. 4, quenching circuitry may also be coupled to the SPAD 100, as noted above. As a photon enters the photosensitive area of the p-substrate 101, it triggers a so-called avalanche in a multiplication region 107 in the deep n-well within the p-well guard ring 104, causing current to flow through the SPAD 100, as will be appreciated by those skilled in the art.

The SPAD 100 further advantageously includes an MST layer 125 between the multiplication region 107 and central p+ area 103 for enhanced junction engineering. More particularly, breakdown voltage (BV) is a very important parameter in the design of SPADs. Depending on the given application, it may be desirable to have a higher or lower BV. That is, higher and lower BVs have advantages and disadvantages and should be optimized depending on the application. More particularly, changes in BV will affect reliability, dark current, and detection efficiency. Since the MST material can control the junction steepness and uniformity, positioning an MST film at the desired position of the p-n junction may advantageously define the desired BV for the intended application.

Defining the junction position with an MST film may also affect the avalanche uniformity across an array of SPAD devices 100 and between different pixels in the array. Moreover, the MST material may also be used to change the absorption spectrum. More particularly, MST films may be used for band structure engineering in Si or other semiconductors, particularly changing the absorption from Si indirect to direct transition. This may advantageously be used for enhancing IR absorption in Si, without a need for III-V semiconductor materials, quantum wells, etc. Further details regarding the use of MST films in different optical absorption applications are set forth in U.S. Pat. Nos. 7,880,161 and 8,389,974, which are also assigned to the present Applicant and are hereby incorporated herein in their entireties by reference.

In the embodiment of FIG. 4, the MST layer 125 is positioned within the multiplication region 107 between the p-well guard ring 104 and at an interface with the central p+ active region 103. This MST layer 125 may advantageously provide enhanced control over the electric field profile within the multiplication region 107 to optimize breakdown voltage characteristics and avalanche initiation uniformity. By precisely positioning the MST layer 125 at a critical location within the electric field, the junction steepness can be engineered to achieve desired performance characteristics including improved timing jitter, reduced after-pulsing probability, and enhanced photon detection efficiency.

The thickness of the MST layer 125 may be selected based upon the desired device characteristics. For example, in some embodiments the MST layer 125 may comprise between 10 to 100 periods of the superlattice structure described above, although other thicknesses may be used depending on the application. The specific composition of the MST layer 125, including the number of semiconductor monolayers in each base semiconductor portion and the coverage percentage of the non-semiconductor monolayers, may also be optimized to achieve the desired electric field profile and breakdown voltage characteristics.

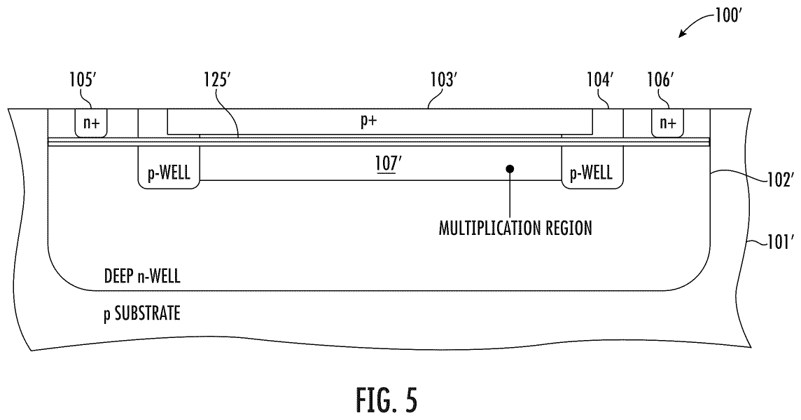

Referring additionally to FIG. 5, in an alternative embodiment the SPAD 100′ may have an MST layer 125′ that extends across the entire deep n-well region 102′ (and optionally across the entire p substrate 101′). That is, rather than being selectively deposited just in the area within the guard ring 104′, a blanket deposition may be performed to form the MST layer 125′ that extends across the entire deep n-well region 102′. This may provide further benefits, such as reduced contact resistance for the contacts 105′, 106′, in addition to those described above. Further details regarding the use of MST films to reduce contact resistance are set forth in U.S. Pat. No. 10,593,761, which is also assigned to the present Applicant and is hereby incorporated herein in its entirety by reference.

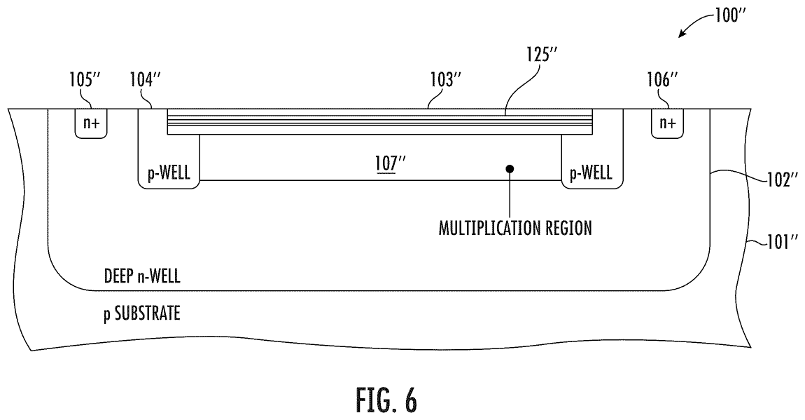

Another SPAD device 100″ variation is provided in FIG. 6. Here, the MST layer 125″ is incorporated in the central p+ active region 103″, rather than in the multiplication region 107″. This may define a different junction position for different applications, as will be appreciated by those skilled in the art.

In the embodiment of FIG. 6, positioning the MST layer 125″ within the central p+ active region 103″ rather than the multiplication region 107″ provides an alternative approach to junction engineering and electric field control. This configuration may be particularly advantageous for applications requiring different breakdown voltage characteristics or where optimization of the electric field distribution at the edge of the p+ region is desirable. The MST layer 125″ in this location can help reduce the concentration of electrically active defects near the junction, thereby improving dark count rate performance and reducing noise in the SPAD device 100″, for example.

Furthermore, the MST layer 125″ positioned in the central p+ active region 103″ may enhance the effectiveness of the p-well guard ring 104″ by creating a more abrupt junction transition. This can help prevent premature edge breakdown and improve the uniformity of the electric field across the active area of the device. The resulting improvement in field uniformity can lead to better timing resolution and reduced pixel-to-pixel variation in large SPAD arrays.

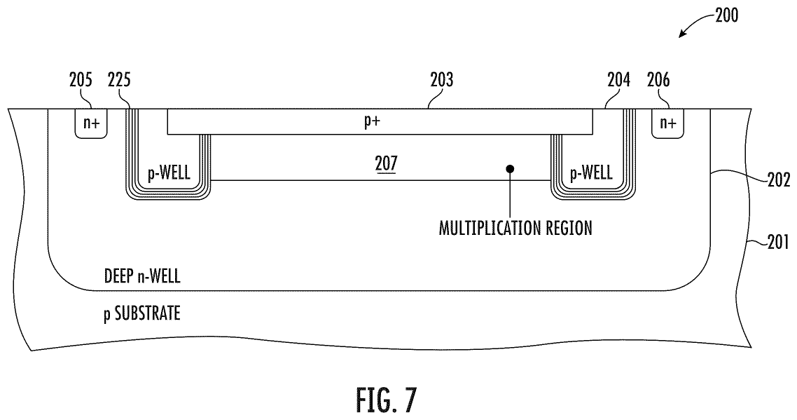

Turning now to FIG. 7, p-well guard ring junction engineering may also important for BV control. In the illustrated example, this is accomplished through the use of an MST film 225 surrounding the p-well guard ring 204 of a SPAD 200. Similar to the SPADs described above, the SPAD 200 illustratively includes a p-type substrate 201 with a deep n-well 202 therein, a central p+ active region 203 (the p-well guard ring 204 surrounding the central p+ region), and contacts 205, 206.

The MST film 225 surrounding the p-well guard ring 204 helps provide precise control over the electric field distribution at the periphery of the active region, which is important for preventing premature edge breakdown and ensuring uniform avalanche initiation. By engineering the junction profile at the guard ring interface, the MST layer 225 may help reduce peak electric fields that might otherwise cause localized breakdown at lower voltages than the main junction.

In this embodiment, the MST layer 225 may be formed by depositing the superlattice structure in a conformal manner in a trench before forming the p-well guard ring 204. This can be accomplished through standard semiconductor processing techniques including atomic layer deposition followed by appropriate patterning steps. The thickness and composition of the MST layer 225 can be optimized to achieve the desired guard ring characteristics while maintaining compatibility with other device processing steps.

The use of the MST layer 225 at the guard ring location may be particularly effective to allow independent optimization of the main junction (within the multiplication region) and the guard ring junction. This dual-junction optimization capability may enable designers to achieve enhanced device performance by separately tuning the breakdown characteristics at each critical location within the SPAD structure.

Moreover, the MST layer 225 may help reduce defect-related dark counts that often originate at the device periphery where the guard ring is located. By improving the crystal quality and reducing interface states at this location, the MST technology may significantly enhance the signal-to-noise ratio of the SPAD device 200, which is particularly important for low-light detection applications such as fluorescence microscopy, quantum key distribution, and LIDAR systems.

It should be noted that in some embodiments, more than one MST film may be used, e.g., a combination of the above-described MST film embodiments in the same SPAD device. Moreover, it should also be noted that the n- and p-type regions described above may be reversed in different embodiments (e.g., the p substrate 101 may instead by n-type, the deep n-well region 102 may be p-type, etc.).

The MST layers described herein may be fabricated using molecular beam epitaxy (MBE), chemical vapor deposition (CVD), atomic layer deposition (ALD), or other suitable epitaxial growth techniques that allow for monolayer-level control. In a typical fabrication sequence, the base semiconductor material (e.g., silicon) is deposited to form the base semiconductor portions, followed by controlled deposition of the non-semiconductor material (e.g., oxygen) to form the non-semiconductor monolayers with the desired coverage percentage.

Referring again to FIG. 4, a method aspect is directed to making a SPAD device 100. The method may include forming a deep n-well 102 in a p-type substrate 101, and forming a central p+ region 103 and a p-well guard ring 104 surrounding the central p+ region in the deep n-well. The method may further include forming an MST layer 125 between a multiplication region 107 in the deep n-well and the central p+ region 103 for enhanced junction engineering, as discussed further above.

The method may further include forming contacts 105, 106 in the deep n-well 102 adjacent the guard ring 104. In some embodiments, the MST layer 125 may be selectively formed only in a region within the guard ring 104, as seen in FIG. 4, while in other embodiments the MST layer may extend across the entire deep n-well region 102′, as seen in FIG. 5.

An alternative method embodiment may include forming the MST layer 125″ in the central p+ region 103″ rather than between the multiplication region and the central p+ region, as seen in FIG. 6. Still another method embodiment may include forming an MST layer 225 surrounding the p-well guard ring 204 for guard ring junction engineering, as seen in FIG. 7.

The method may further include optimizing a thickness of the MST layer based upon desired breakdown voltage characteristics and detection efficiency requirements for the specific application. The composition of the MST layer, including the selection of base semiconductor material and non-semiconductor material, may also be optimized based on the desired electrical and optical properties of the SPAD device, as discussed further above.

The integration of MST technology into SPAD devices as described herein provides numerous technical advantages that may enhance device performance across multiple dimensions. First, the ability to precisely control breakdown voltage through MST layer positioning and composition enables optimization of the trade-off between detection efficiency, timing jitter, and dark count rate for specific applications.

Second, the improved junction quality resulting from the MST layers helps reduce defect-related noise sources, leading to lower dark count rates and improved signal-to-noise ratios. This may be particularly valuable in photon-starved applications where single-photon sensitivity is critical.

In addition, the enhanced uniformity of the electric field distribution achieved through MST junction engineering helps reduce pixel-to-pixel variation in large SPAD arrays. This improved uniformity translates to better array-level performance and simplified calibration requirements for imaging applications.

Another advantage is that the band structure engineering capabilities of MST layers enable modification of the absorption spectrum, potentially extending the useful wavelength range of silicon-based SPADs into the near-infrared region without requiring expensive III-V semiconductor materials. Still another advantage is that the barrier properties of MST layers may reduce unwanted diffusion of dopants and other species during high-temperature processing steps, leading to improved process control and device reliability over the operational lifetime of the SPAD. Moreover, the compatibility of MST layers with standard CMOS processing techniques means that these performance enhancements may be achieved without requiring exotic materials or equipment, facilitating commercial adoption and high-volume manufacturing.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that other modifications and embodiments are intended to be included within the scope of the appended claims.

1. A single-photon avalanche diode (SPAD) device comprising:
a semiconductor substrate having a first conductivity type;
a deep well region in the semiconductor substrate having a second conductivity type different than the first conductivity type;
a multiplication region in the deep well region having the second conductivity type;
a central active region on the multiplication region and having the first conductivity type;
a guard ring surrounding the central active region and the multiplication region and having the first conductivity type; and
a superlattice layer adjacent an interface between the multiplication region and the guard ring, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

2. The SPAD device of claim 1 wherein the superlattice layer surrounds the guard ring.

3. The SPAD device of claim 1 comprising a plurality of contact regions adjacent the guard ring.

4. The SPAD device of claim 1 wherein the first conductivity type comprises p-type, and the second conductivity type comprises n-type.

5. The SPAD device of claim 1 wherein the base semiconductor comprises silicon.

6. The SPAD device of claim 1 wherein the base semiconductor comprises germanium.

7. The SPAD device of claim 1 wherein the at least one non-semiconductor monolayer comprises a non-semiconductor selected from the group consisting of oxygen, nitrogen, fluorine, carbon, and carbon-oxygen.

8. The SPAD device of claim 1 wherein the at least one non-semiconductor monolayer comprises oxygen.

9. A single-photon avalanche diode (SPAD) device comprising:
a semiconductor substrate having p-type conductivity;
a deep well region in the semiconductor substrate having n-type conductivity;
a multiplication region in the deep well region having n-type conductivity;
a central active region on the multiplication region and having p-type conductivity;
a guard ring surrounding the central active region and the multiplication region and having p-type conductivity; and
a superlattice layer surrounding the guard ring, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

10. The SPAD device of claim 9 comprising a plurality of contact regions adjacent the guard ring.

11. The SPAD device of claim 9 wherein the base semiconductor comprises silicon.

12. The SPAD device of claim 9 wherein the base semiconductor comprises germanium.

13. The SPAD device of claim 9 wherein the at least one non-semiconductor monolayer comprises a non-semiconductor selected from the group consisting of oxygen, nitrogen, fluorine, carbon, and carbon-oxygen.

14. The SPAD device of claim 9 wherein the at least one non-semiconductor monolayer comprises oxygen.

15. A single-photon avalanche diode (SPAD) device comprising:
a semiconductor substrate having a first conductivity type;
a deep well region in the semiconductor substrate having a second conductivity type different than the first conductivity type;
a multiplication region in the deep well region having the second conductivity type;
a central active region on the multiplication region and having the first conductivity type;
a guard ring surrounding the central active region and the multiplication region and having the first conductivity type; and
a superlattice layer adjacent an interface between the multiplication region and the guard ring, the superlattice layer comprising a plurality of stacked groups of layers, each group of layers comprising a plurality of stacked base silicon monolayers defining a base silicon portion, and at least one oxygen monolayer constrained within a crystal lattice of adjacent base silicon portions.

16. The SPAD device of claim 15 wherein the superlattice layer surrounds the guard ring.

17. The SPAD device of claim 15 comprising a plurality of contact regions adjacent the guard ring.

18. The SPAD device of claim 15 wherein the first conductivity type comprises p-type, and the second conductivity type comprises n-type.
